(19) United States
(12) Patent Application Publication
(10) Pub. No.: US 2016/0183392 A1
(43) Pub. Date: Jun. 23, 2016

(54) Electronic Device Holder

(71) Applicant: Amie Kelley, Baneberry, TN (US)

(72) Inventor: Amie Kelley, Baneberry, TN (US)

(21) Appl. No.: 14/734,178

(22) Filed: Jun. 9, 2015

Related U.S. Application Data
(60) Provisional application No. 62/094,642, filed on Dec. 19, 2014.

(51) Int. Cl. H05K 5/02; F16L 3/12; F16L 3/06

(52) U.S. Cl. CPC H05K 5/0204; F16L 3/06; F16L 3/12

(57) ABSTRACT

An electronic device holder for storing and organizing electronic devices. The electronic device holder includes a main pocket having a front panel and a rear panel, wherein one or more secondary pockets are secured to the front panel of the main pocket. The main pocket and secondary pockets each include a base, one or more sidewalls, and an open upper end. The main pocket can hold a tablet or computer notebook therein, wherein the secondary pockets can hold smaller electronic devices therein, such as cell phones or media players. The rear panel of the main pocket includes one or more fasteners that allow the electronic device holder to be removably secured to a vertical surface without causing damage thereto. Additionally, the rear panel of the main pocket includes a kickstand that can support the device in an upright position on a horizontal surface.

### CROSS REFERENCE TO RELATED APPLICATION

This application claims the benefit of U.S. Provisional Application No. 62/094,642 filed on Dec. 19, 2014. The above identified patent application is herein incorporated by reference in its entirety to provide continuity of disclosure.

### BACKGROUND OF THE INVENTION

### Field of the Invention

The present invention relates to electronic device holders. More specifically, the present invention provides an electronic device holder comprising a main pocket adapted to receive a large electronic device therein, such as a tablet, and one or more secondary pockets secured to the front panel of the main pocket. The secondary pocket is adapted to hold a smaller electronic device therein, such as a cell phone.

People use several different electronic devices throughout the day, including cell phones, tablets, e-book readers, and the like. However, when these electronic devices are not actively in use, they are temporarily set aside. The electronic devices are set upon countertops in the kitchen, living room, and the like, thereby creating a cluttered, messy appearance in a home. Additionally, leaving electronic devices in this manner allows them to become easily lost or misplaced, leading to frustration and time wasted in searching for the electronic device. Furthermore, when an individual charges their electronic device, the electronic device along with the charging wires are strewn about floors, tables, and counter space. These electronic devices are easily stepped on and damaged if left lying on the floor. Therefore, there exists a need in the prior art for a holder that supports handheld electronic devices of varying size in an organized manner, thereby improving access thereto.

It is submitted that the present invention substantially diverges in design elements from the prior art and consequently it is clear that there is a need in the art for an improvement to existing electronic device holders. In this regard the instant invention substantially fulfills these needs.

### SUMMARY OF THE INVENTION

In view of the foregoing disadvantages inherent in the known types of electronic device holders now present in the prior art, the present invention provides a new electronic device holder wherein the same can be utilized for providing convenience for the user when storing or charging an electronic device.

It is therefore an object of the present invention to provide a new and improved electronic device holder that has all of the advantages of the prior art and none of the disadvantages.

It is another object of the present invention to provide an electronic device holder comprising a main pocket having a base, a front panel, a rear panel, one or more sidewalls, and an open upper end, wherein the main pocket is adapted to hold a large electronic device therein, such as a tablet.

Another object of the present invention is to provide an electronic device holder further comprising one or more secondary pockets secured to the front panel of the main pocket and adapted to hold smaller electronic devices therein, such as a cell phone.

Yet another object of the present invention is to provide an electronic device holder wherein the rear panel of the main pocket comprises one or more fasteners adapted to removably secure the device to a vertical surface.

Yet another object of the present invention is to provide an electronic device holder further comprising a kickstand adjustably secured to the rear panel of the main pocket in order to support the device in an upright position on a horizontal surface.

Yet another object of the present invention is to provide an electronic device holder further comprising a wire holder disposed on one or more sidewalls of the main pocket and secondary pockets, adapted to receive a wire wound therearound.

Yet another object of the present invention is to provide an electronic device holder further comprising a slot disposed on the upper end of the sidewall comprising the pair of L-shaped flanges, wherein the slot is adapted to receive a wire therethrough.

Yet another object of the present invention is to provide an electronic device holder wherein, in an alternative embodiment, the electronic device holder comprises one or more secondary pockets, wherein a rear panel of the secondary pockets comprises one or more fasteners adapted to secure the holder to a wall and a kickstand adapted to support the holder in an upright orientation.

Another object of the present invention is to provide an electronic device holder that may be readily fabricated from materials that permit relative economy and are commensurate with durability.

Other objects, features and advantages of the present invention will become apparent from the following detailed description taken in conjunction with the accompanying drawings.

### BRIEF DESCRIPTIONS OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows a perspective view of an embodiment of the electronic device holder.

FIG. 2 shows a rear perspective view of an embodiment of the electronic device holder.

FIG. 3 shows a perspective view of alternative embodiment of the electronic device holder.

### DETAILED DESCRIPTION OF THE INVENTION

Reference is made herein to the attached drawings. Like reference numerals are used throughout the drawings to depict like or similar elements of the electronic device holder. For the purposes of presenting a brief and clear description of the present invention, the preferred embodiment will be discussed as used for holding an electronic device therein when storing or charging the electronic device. The figures are intended for representative purposes only and should not be considered to be limiting in any respect.

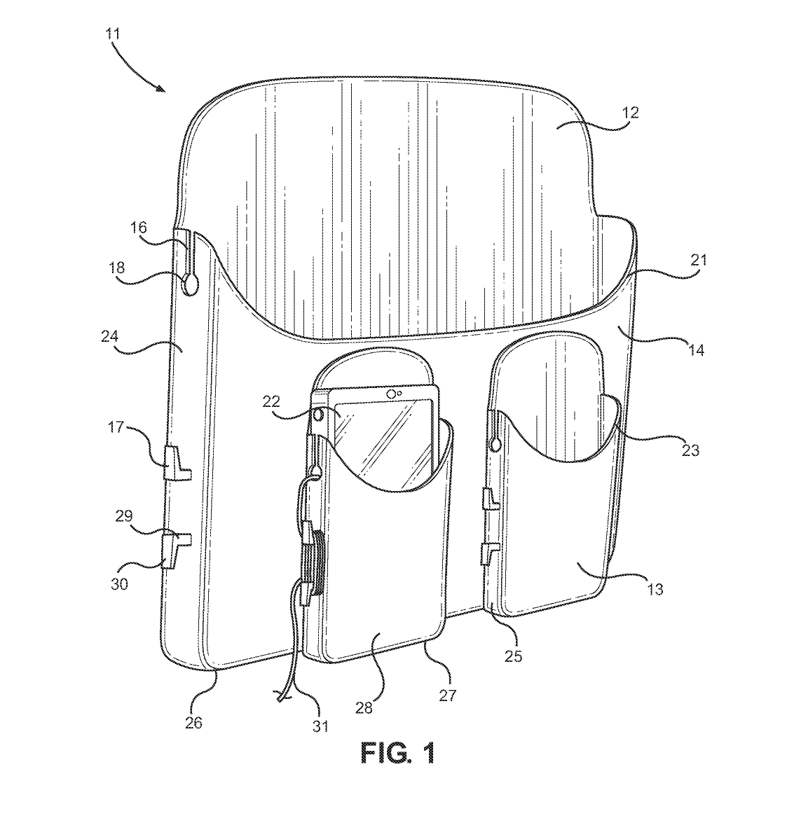

Referring now to FIG. 1, there is shown a perspective view of an embodiment of the electronic device holder. The electronic device holder 11 comprises a main pocket 12 adapted to a hold a large electronic device therein, such as laptop computer or tablet, among others. The main pocket 12 comprises a base 26, one or more sidewalls 24, a front panel 14 opposing a rear panel, and an open upper end 21.

The electronic device holder 11 further comprises one or more secondary pockets 13 each having a base 27, one or more sidewalls 25, a front panel 28 opposing a rear panel, and an open upper end 23, defining an interior volume therein. The open upper end 23 of the secondary pockets 13 are adapted to receive smaller electronic devices 22 therein, such as a cell phone. The main pocket 12 and secondary pockets 13 are adapted to hold the electronic devices 22 in an upright, vertical manner. The edges of the electronic devices 22 are adapted to rest on the base 26, 27 of the main pocket 12 and secondary pockets 13, whereas the rear and front panels of the electronic devices 22 are adapted to rest against the sidewalls 24, 25 of the pockets 12, 13.

The rear panel of the secondary pockets 13 are secured to the front panel 14 of the main pocket 12. The main pocket 12 and the secondary pockets 13 are secured to one another by any suitable fastener, such as adhesive. The front panel 14 of the main pocket 12 and the rear panel of the secondary pocket 13 are flush against one another. The configuration of the main pocket 12 and the secondary pockets 13 allow for multiple electronic devices 22 to be stored and charged in an efficient manner in order for the electronic device holder 11 to have a compact configuration.

The main pocket 12 and secondary pockets 13 are similar in configuration, wherein both pockets 12, 13 are rectangular in shape. The upper end 21, 23 of the front panel 14, 28 of the main pocket 12 and secondary pockets 13 each comprise a concave curvature, whereas the upper end 21, 23 of the rear panel comprise a convex curvature. The concave upper end 21, 23 allows the front panel 14, 28 to be positioned lower than the sidewalls 24, 25 and the rear panel. The lower positioned front panel 14, 18 is adapted to expose a portion of an electronic device 22 stored within the main pocket 12 and secondary pocket 13 so as to allow a user to easily access and remove the electronic device 22 therefrom. Furthermore, the rear panel is preferably taller than the front panel 14, 28 so as to provide front access to the electronic device 22 disposed therein, particularly if the rear panel of the electronic device holder 11 is secured to a wall. The rear panel further provides an area for an electronic device to rest against, thereby protecting a wall or other vertical surface from having the electronic device placed directly thereagainst, which can lead to marks or damage thereto.

The electronic device holder 11 further comprises one or more slots 16 disposed at the upper end 21, 23 of the sidewalls 24, 25 of the main pocket 12 and the secondary pockets 13. A slot 16 is adapted to receive one or more wires 31 therethrough, wherein the wires 31 are connected to an electronic device 22 positioned within the main pocket 12 or secondary pocket 13. The wire 31 can be from an electronic device charger or other apparatus, such as a pair of headphones. Each slot 16 is vertically oriented and comprises a first end opposing a second end. The first end of the slot 16 is open and adapted to receive the wire 31 therein. The second end of the slot 16 comprises an aperture 18 that allows the wire 31 to rest thereon. The wire 31 disposed in the aperture 18 is adapted to move freely. However, the size of the first end of the slot 16 is adapted to prevent the wire 31 from becoming easily removed therefrom. The slot 16 further prevents the wire 31 from moving beyond the sidewall 24, 25 that it is disposed through and becoming tangled around the electronic device 22. The slot 16 is adapted to direct a wire disposed therein downward in an organized manner so the wire 31 can be wound around a pair of L-shaped flanges 17.

The electronic device holder 11 further comprises a wire holder. The wire holder 17 includes one or more flanges that extend outwardly from the sidewalls 24, 25 of the main pocket 12 and secondary pocket 13. In the illustrated embodiment, the wire holder 17 comprises a pair of L-shaped flanges 17 disposed on the sidewalls 24 of the main pocket 12 and the sidewalls 25 of the secondary pockets 13. The pair of L-shaped flanges 17 are disposed on the same sidewalls 24, 25 comprising a slot 16 and are positioned beneath the slot 16. The pair of flanges 17 are adapted to receive the wire 31 extending from the slot 16, wherein the wire 31 can be wound around the pair of flanges 17. The pair of L-shaped flanges 17 are vertically aligned, wherein one flange 17 is positioned below the other flange 17. Each L-shaped flange 17 comprises a horizontal section 29 extending outward and perpendicularly from a sidewall 24, 25, wherein the horizontal section 29 is orthogonally connected to a vertical section 30. The vertical section 30 is parallel to the sidewall 24, 25. The horizontal sections 29 are adapted to receive a wire 31 wound therearound, whereas the vertical sections 30 of each pair of flanges 17 face in opposing directions of one another so as to be able to provide a barrier from the wire 31 sliding off the horizontal sections 29. The slot 16 and flanges 17 allow the wires 31 connected to the electronic device 22 to be positioned so that the electronic device 22 can be charged while resting within the electronic device holder 11. The slot 16 and flanges 17 further provide organization for other wires 31 connected to the electronic device 22.

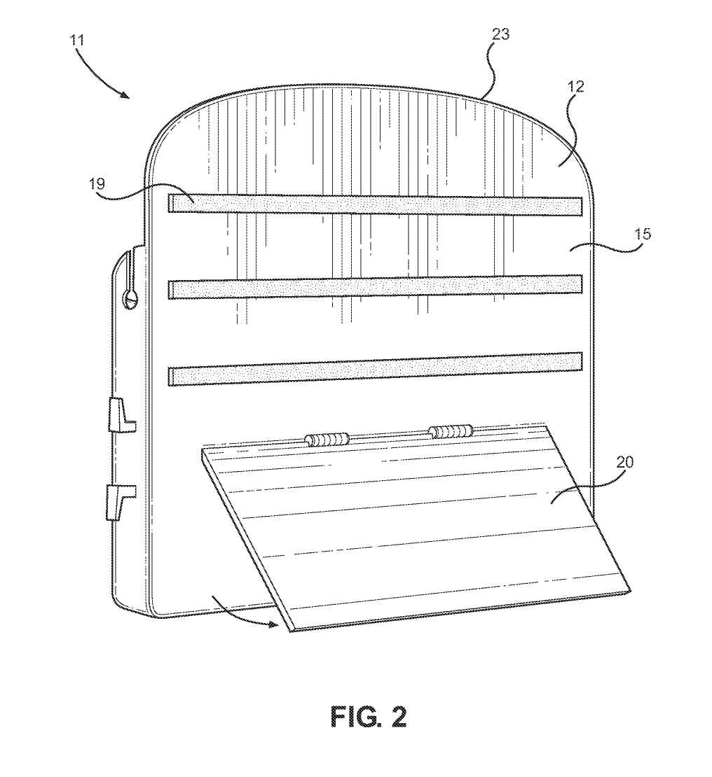

Referring now to FIG. 2, there is shown a rear perspective view of an embodiment of the electronic device holder. The electronic device holder 11 is adapted to be removably secured to a vertical surface, such as a wall, or placed on a horizontal surface, such as a kitchen countertop. The rear panel 15 of the main pocket 12 comprises one or more fasteners 19 adapted to removably secure the electronic device holder 11 to a wall. In the illustrated embodiment, the fasteners 19 are elongated strips of adhesive material, wherein the strips of adhesive material are disposed horizontally on the rear panel 15 of the main pocket 12. In some embodiments, the fasteners 19 comprise one or more apertures disposed on the upper end of the rear panel that allow the holder 11 to be hung from one or more hooks disposed on the wall. In other embodiments, any suitable fastener 19 can be used to removably secure the electronic device holder 11 to the wall, such as magnets, in order to allow the device to secure to a magnetic surface.

The electronic device holder 11 further comprises a kickstand 20 pivotally secured to the rear panel 15 of the main pocket 12. The kickstand 20 is rectangular in shape and adapted to support the electronic device holder 11 in an upright manner on a horizontal surface when it is not supported by a vertical surface. The kickstand 20 is rigid and planar, wherein it can be pivoted rearward to allow the holder 11 to be tilted and supported by the kickstand 20. The kickstand 20 can be positioned flush against the rear panel 15 of the main pocket 15 and is adapted to fold out therefrom. The kickstand 20 is positioned below the fasteners 19 so the kickstand 20 does not cover the fasteners 19. In this way, the fasteners 19 and kickstand 20 can be used interchangeably without one obstructing the function of the other. The kickstand 20 is secured to the rear panel 15 by any suitable attachment mechanism, such as a hinge or a flexible piece of material connecting the main pocket 12 to the kickstand 20. In other embodiments, the kickstand 20 can be any suitable shape, such as a semi-circle, as long as the kickstand 20 is adapted to hold the electronic device holder 11 in an upright position.

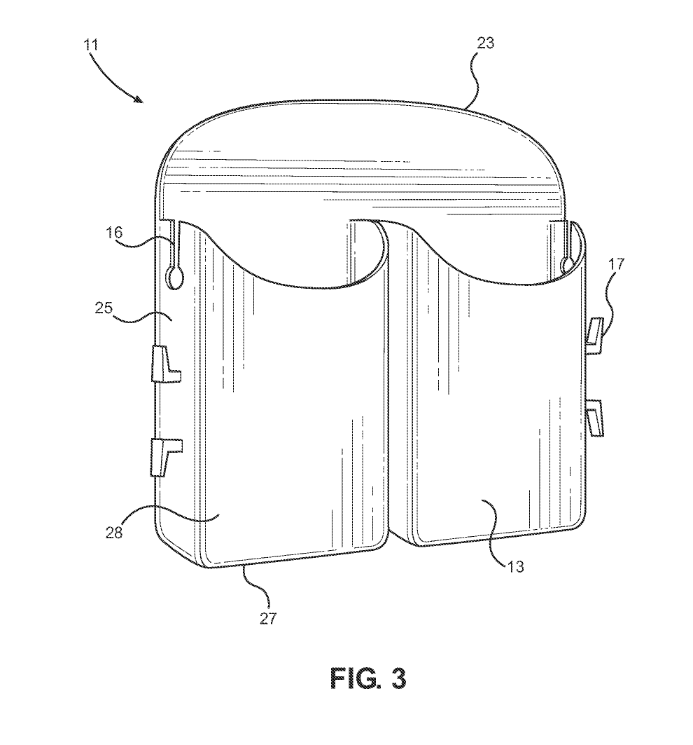

Referring now to FIG. 3, there is shown an alternative embodiment of the electronic device holder. In an alternative embodiment, the electronic device holder 11 comprises one or more secondary pockets 13 having a base 27, one or more sidewalls 25, a front panel 28 opposing a rear panel, and an open upper end 23, defining an interior volume therein. In the illustrated alternative embodiment, a first secondary pocket 13 is disposed next to a second secondary pocket 13, wherein the first and second secondary pockets 13 share a rear panel. The rear panel of the secondary pockets 13 is adapted to be removably secured to a vertical surface, such as a wall, or placed on a horizontal surface, such as a kitchen countertop. The rear panel comprises one or more fasteners adapted to removably secure the holder 11 to a wall and a kickstand adapted to support the holder 11 in an upright position on a horizontal surface. The alternative embodiment of the electronic device holder 11 further comprises one or more pairs of flanges 17 disposed on a sidewall 25 of the secondary pockets 13 and a slot 16 disposed on the same sidewall 25 thereof. The alternative embodiment of the electronic device holder 11 is adapted to provide a user with a holder 11 that can receive and support smaller electronic devices therein.

It is therefore submitted that the instant invention has been shown and described in what is considered to be the most practical and preferred embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1) An electronic device holder, comprising:
a main pocket comprising a base, one or more sidewalls, a front panel, a rear panel, and an open upper end adapted to receive an electronic device therein;
a kickstand pivotally secured to said rear panel of said main pocket and adapted to support said main pocket in an upright position on a horizontal surface;
a wire holder disposed on said one or more sidewalls of said main pocket, wherein a wire connected to said electronic device can be wound therearound;
one or more slots disposed on an upper end of said one or more sidewalls of said main pocket adapted to receive said wire connected to said electronic device therethrough.

2) The electronic device holder of claim 1, further comprising one or more secondary pockets having a base, one or more sidewalls, a rear panel, a front panel, and an open upper end adapted to receive an electronic device therein, wherein said rear panel of said one or more secondary pockets is secured to said front panel of said main pocket.

3) The electronic device holder of claim 2, wherein said one or more secondary pockets comprise a wire holder disposed on said one or more sidewalls of said one or more secondary pockets, wherein a wire connected to said electronic device can be wound therearound.

4) The electronic device holder of claim 3, wherein said wire holder disposed on said one or more sidewalls of said one or more secondary pockets is a pair of L-shaped flanges.

5) The electronic device holder of claim 2, wherein said one or more secondary pockets comprises one or more slots disposed on an upper end of said one or more sidewalls adapted to receive a wire connected to said electronic device therethrough.

6) The electronic device holder of claim 1, further comprising one or more fasteners disposed on said rear panel of said main pocket adapted to removably secure said main pocket to a vertical surface.

7) The electronic device holder of claim 1, further comprising an adhesive disposed on said rear panel of said main pocket.

8) The electronic device holder of claim 1, wherein said wire holder is a pair of L-shaped flanges.

9) The electronic device holder of claim 1, wherein an upper end of said front panel of said main pocket comprises a concave curvature.

10) The electronic device holder of claim 1, wherein an upper end of said rear panel of said main pocket comprises a convex curvature.

11) An electronic device holder, comprising:
one or more secondary pockets comprising a base, one or more sidewalls, a front panel, a rear panel, and an open upper end adapted to receive an electronic device therein;
a support disposed on said rear panel of said one or more secondary pockets adapted to support said one or more secondary pockets in an upright position;
a wire holder disposed on said one or more sidewalls of said one or more secondary pocket, wherein a wire connected to said electronic device can be wound therearound;
one or more slots disposed on an upper end of said one or more sidewalls of said one or more secondary pockets adapted to receive said wire connected to said electronic device therethrough.

12) The electronic device holder of claim 11, wherein an upper end of said front panel comprises a concave curvature.

13) The electronic device holder of claim 11, wherein an upper end of said rear panel comprises a convex curvature.

14) The electronic device holder of claim 11, further comprising one or more fasteners disposed on said rear panel of said one or more secondary pockets adapted to removably secure said one or more secondary pockets to a vertical surface.

15) The electronic device holder of claim 14, wherein said one or more fasteners is an adhesive.

16) The electronic device holder of claim 11, wherein said wire holder is a pair of L-shaped flanges.
